(19) United States
(12) Patent Application Publication
(10) Pub. No.: US 2006/0205237 A1
(43) Pub. Date: Sep. 14, 2006

(54) Preparation of semiconductor device

(75) Inventors: Kinya Kodama, Gunma-ken (JP); Tsutomu Kashiwagi, Gunam-ken (JP); Katsuyuki Imazawa, Gunma-ken (JP)

Correspondence Address: BIRCH STEWART KOLASCH & BIRCH, PO BOX 747, FALLS CHURCH, VA, 22040-0747, US

(73) Assignee: Shin-Etsu Chemical Co, Ltd.

(21) Appl. No.: 11/360,413

(22) Filed: Feb. 24, 2006

(30) Foreign Application Priority Data
Mar. 10, 2005 (JP) 2005-067587

(51) Int. Cl. H01L 21/31; H01L 21/469

(52) U.S. Cl. 438/790

(57) ABSTRACT

In the preparation of a semiconductor device comprising a semiconductor member, the semiconductor member is subjected to plasma treatment and then primer treatment, prior to the encapsulation thereof with an encapsulant. The semiconductor device, typically LED package, is highly reliable in that a firm bond is established between the semiconductor member and the encapsulant resin.

### CROSS-REFERENCE TO RELATED APPLICATION

This non-provisional application claims priority under 35 U.S.C. §119(a) on Patent Application No. 2005-067587 filed in Japan on Mar. 10, 2005, the entire contents of which are hereby incorporated by reference.

### TECHNICAL FIELD

This invention relates to a method for preparing semiconductor devices, typically LED packages, and more particularly, to a method for preparing a semiconductor device such that a firm bond is established between a semiconductor member and an encapsulant resin. As used herein, the term “semiconductor member” is used to denote both a semiconductor chip and a substrate having a semiconductor chip mounted thereon.

### BACKGROUND ART

In general, semiconductor devices are encapsulated and protected with various resins for protecting semiconductor chips on substrates or lead frames. To enhance the reliability of such semiconductor packages, a firm bond or close contact must be established between the semiconductor member and the encapsulant resin. However, in rigorous thermal cycling tests and moisture resistance tests, the current packages will give rise to some problems like delamination between the semiconductor member and the encapsulant resin. There still exists a need for a technology of fabricating more reliable semiconductor devices.

A variety of primers have been proposed in the art for enhancing the reliability of semiconductor devices. There still remains a demand for a method of fabricating semiconductor devices that withstand harsh conditions.

Patents pertinent to the present invention include JP-B 03-054715, JP-A 05-179159 corresponding to U.S. Pat. No. 5,213,617 and U.S. Pat. No. 5,238,708, JP-B 07-091528, JP-A 2004-079683, and JP-A 2004-339450.

### DISCLOSURE OF THE INVENTION

An object of the present invention is to provide a method for preparing a semiconductor device, typically an LED package, which is highly reliable in that a firm bond is established between a semiconductor member and an encapsulant resin serving as a protective layer.

The inventor has found that by treating a semiconductor member with plasma, priming it with a primer composition, and thereafter encapsulating it with an encapsulating resin to form a protective layer, an enhanced adhesion is established between the semiconductor member and the protective layer. As a result, the semiconductor device is improved in reliability.

According to the invention, there is provided a method for preparing a semiconductor device comprising a semiconductor member, the method comprising the steps of subjecting the semiconductor member to plasma treatment, subjecting the semiconductor member to primer treatment with a primer composition, and thereafter, encapsulating the semiconductor member with an encapsulant.

Most often, the semiconductor device is an LED package.

In a preferred embodiment, the primer composition comprises a silane coupling agent and/or a partial hydrolytic condensate thereof and optionally, a diluent. The primer composition may further comprise a condensation catalyst.

In another preferred embodiment, the primer composition comprises an organosiloxane oligomer having the average compositional formula (1):
R¹ₐR²_{b}R³_{c}R⁴_{d}(OR)⁵)ₑSiO_{(4-a-b-c-d-e)/2} (1)
wherein R¹ is a monovalent organic group of 2 to 30 carbon atoms having at least one epoxide, R² is a monovalent hydrocarbon group of 2 to 30 carbon atoms having at least one unconjugated double bond group, R³ is a monovalent organic group of 3 to 30 carbon atoms having at least one (meth)acrylic functional group, R⁴ is hydrogen or a monovalent hydrocarbon group of 1 to 20 carbon atoms, R⁵ is hydrogen or a substituted or unsubstituted, monovalent hydrocarbon group of 1 to 10 carbon atoms, the subscripts a, b, c, d and e are numbers satisfying the range: 0.1≦a≦1.0, 0≦b≦0.6, 0≦c≦0.6, 0≦d≦0.8, 1.0≦e≦2.0, and 2.0≦a+b+c+d+e≦3.0, and optionally, a diluent.

The organosiloxane oligomer having the formula (1) is typically obtained through (co)hydrolytic condensation of at least one silane compound having the general formula (2):
R¹ₓR⁴_{y}Si(OR⁵)_{4-x-y} (2)
wherein R¹ is a monovalent organic group of 2 to 30 carbon atoms having at least one epoxide, R⁴ is a monovalent hydrocarbon group of 1 to 20 carbon atoms, R⁵ is hydrogen or a substituted or unsubstituted, monovalent hydrocarbon group of 1 to 10 carbon atoms, x is 1 or 2, and y is 0 or 1, the sum of x+y is 1 or 2, and optionally, at least one silane compound having the general formula (3):
R²ₓR⁴_{y}Si(OR⁵)_{4-x-y} (3)
wherein R² is a monovalent hydrocarbon group of 2 to 30 carbon atoms having at least one unconjugated double bond group, R⁴ is a monovalent hydrocarbon group of 1 to 20 carbon atoms, R⁵ is hydrogen or a substituted or unsubstituted, monovalent hydrocarbon group of 1 to 10 carbon atoms, x is 1 or 2, and y is 0 or 1, the sum of x+y is 1 or 2, and optionally, at least one silane compound having the general formula (4):
R³ₓR⁴_{y}Si(OR⁵)_{4-x-y} (4)
wherein R³ is a monovalent organic group of 3 to 30 carbon atoms having at least one (meth)acrylic functional group, R⁴ is a monovalent hydrocarbon group of 1 to 20 carbon atoms, R⁵ is hydrogen or a substituted or unsubstituted, monovalent hydrocarbon group of 1 to 10 carbon atoms, x is 1 or 2, and y is 0 or 1, the sum of x+y is 1 or 2, and optionally, at least one silane compound having the general formula (5):
R⁴₂Si(OR⁵)_{4-z} (5)
wherein R⁴ is hydrogen or a monovalent hydrocarbon group of 1 to 20 carbon atoms, R⁵ is hydrogen or a substituted or unsubstituted, monovalent hydrocarbon group of 1 to 10 carbon atoms, and z is an integer of 1 to 3. The primer composition may further comprise a condensation catalyst.

Preferably the encapsulant forms a transparent cured product. The preferred encapsulant comprises a curable resin selected from among a curable silicone resin, curable epoxy-silicone hybrid resin, curable epoxy resin, curable acrylic resin and curable polyimide resin.

In a preferred embodiment, the plasma treatment uses a gas selected from among argon, nitrogen, oxygen, air and mixtures thereof.

### BENEFITS OF THE INVENTION

The semiconductor device, typically LED package, fabricated by the invention is highly reliable since a firm bond is established between the semiconductor member and the encapsulant resin. The invention is advantageous particularly when applied to LED devices.

### BRIEF DESCRIPTION OF THE DRAWING

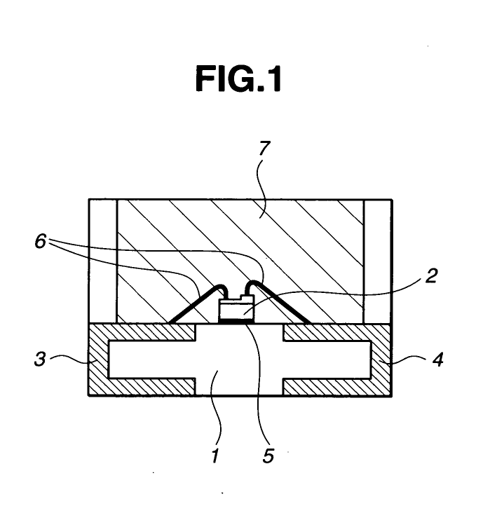

The only figure, FIG. 1 is a cross-sectional view of a light-emitting diode package as one exemplary surface mount semiconductor device in which a light-emitting diode is die-bonded to an insulating housing.

### DESCRIPTION OF THE PREFERRED EMBODIMENTS

As used herein, the terminology “(meth)acrylic” is intended to mean acrylic or methacrylic.

The method of the invention is characterized by pretreatments prior to the encapsulation of a semiconductor member with an encapsulant resin. The pretreatments include plasma treatment and subsequent primer treatment. These pretreatments serve to render the resulting semiconductor device more reliable.

The method of preparing semiconductor devices according to the invention is described in detail.

Semiconductor Member

As noted in the preamble, both a semiconductor chip (or element) and a substrate having a semiconductor chip mounted thereon are collectively referred to as “semiconductor member” throughout the specification.

The semiconductor chip the present invention addresses is not particularly limited. Suitable semiconductor chips include transistors, diodes, capacitors, varisters, thyristors, and photoelectric conversion elements, and inter alia, optical semiconductor elements such as light-emitting diodes, photo-transistors, photo-diodes, CCD, solar battery modules, EPROM, and photo-couplers. More advantages are obtained when light-emitting diodes (LED) are used. Also included are substrates having such semiconductor chips mounted thereon.

Plasma Treatment

According to the invention, plasma treatment is carried out by placing the semiconductor member on an electrode in a vacuum chamber, evacuating the chamber to vacuum, feeding a gas for plasma treatment to the chamber, and applying a voltage across the electrodes to generate a plasma in the chamber, thereby treating or cleaning the surface of the semiconductor member by an etching effect. The source gas for plasma treatment may be argon, nitrogen, oxygen, chlorine, bromine or fluorine or a mixture thereof. In order that the plasma treatment be more effective for improving adhesion, the plasma treatment is desirably carried out in an atmosphere of air, oxygen, chlorine, bromine or fluorine. For some packages, the use of inert gases such as argon and nitrogen is desired.

Effective plasmas include radio frequency (RF) plasma, microwave plasma, electron cyclotron resonance (ECR) plasma and the like, any of which is applicable in the invention. With respect to the frequency and power of plasma, a power of up to about 1,000 W, especially about 10 to 500 W at a frequency of 13.56 MHz is preferred. The vacuum in the plasma treatment system (chamber) is preferably about 100 to 0.1 Pa, especially about 50 to 1 Pa.

The distance of plasma irradiation to the semiconductor member surface is generally about 0.1 to 500 mm, preferably about 0.5 to 30 mm although the distance varies with the power of the plasma irradiating system, the shape of the nozzle and the like. As regards the time of plasma irradiation, irradiation within 30 minutes is sufficient, with the preferred irradiation time being about 0.1 to 600 seconds, more preferably about 0.5 to 600 seconds.

Also, the plasma treatment may be preceded by the step of cleaning the semiconductor member with a solvent or the like using a ultrasonic cleaning machine, spray or the like, or the step of blowing off dust and debris using compressed air.

Primer Treatment

The plasma-treated semiconductor member is then primed with a primer composition.

Primer Composition

The primer composition used herein may be any of well-known primer compositions. Typical is a primer composition comprising a silane coupling agent or a partial hydrolytic condensate thereof and optionally, a diluent. Examples of the silane coupling agent and its partial hydrolytic condensate include vinyltrichlorosilane, vinyltrimethoxysilane, vinyltriethoxysilane, 2-(3,4-epoxycyclohexyl)ethyltrimethoxysilane, 3-glycidoxypropyltrimethoxysilane, 3-glycidoxypropylmethyldiethoxysilane, 3-glycidoxypropyltriethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, N-2-(aminoethyl)-3-aminopropylmethyldimethoxysilane, N-2-(aminoethyl)-3-aminopropyltrimethoxysilane, N-2-(aminoethyl)-3-aminopropyltriethoxysilane, 3-aminopropyltrimethoxysilane, 3-aminopropyltriethoxysilane, N-phenyl-3-aminopropyltrimethoxysilane, 3-chloropropyltrimethoxysilane, 3-mercaptopropyltrimethoxysilane, as well as trimethoxysilane, tetramethoxysilane and oligomers thereof, and mixtures thereof.

In one preferred embodiment, a primer composition comprising an epoxide-containing organosiloxane oligomer having the average compositional formula (1) and optionally, a diluent is used.
R¹ₐR²_{b}R³_{c}R⁴_{d}(OR⁵)ₑSiO_{(4-a-b-c-d-e)/2} (1)
Herein R¹ is a monovalent organic group of 2 to 30 carbon atoms having at least one epoxide, R² is a monovalent hydrocarbon group of 2 to 30 carbon atoms having at least one unconjugated double bond group, R³ is a monovalent organic group of 3 to 30 carbon atoms having at least one (meth)acrylic functional group, R⁴ is hydrogen or a monovalent hydrocarbon group of 1 to 20 carbon atoms, and R⁵ is hydrogen or a substituted or unsubstituted, monovalent hydrocarbon group of 1 to 10 carbon atoms. The subscripts a, b, c, d and e are numbers satisfying the range: 0.1≦a≦1.0, 0≦b≦0.6, 0≦c≦0.6, 0≦d≦0.8, 1.0≦e≦2.0, and 2.0≦a+b+c+d+e≦3.0. Preferably, a, b, c, d and e are numbers satisfying the range: 0.2≦a≦0.9, 0.1≦b≦0.6, 0≦c≦0.4, 0≦d≦0.6, 1.2≦e≦1.7, and 2.2≦a+b+c+d+e≦3.0. This organosiloxane oligomer generally has a weight average molecular weight of about 300 to 30,000, preferably about 400 to 10,000, more preferably about 500 to 5,000, as measured by gel permeation chromatography (GPC) versus polystyrene standards.

In more preferred embodiment, the organosiloxane oligomer having the formula (1) is a (co)hydrolytic condensate of a silane mixture containing one or more epoxy-modified organoxysilane represented by the general formula (2), and optionally one or more unconjugated double bond-bearing organoxysilane represented by the general formula (3), and optionally one or more (meth)acrylic-modified organoxysilane having a photo-polymerizable (meth)acrylic structure represented by the general formula (4), and optionally one or more organoxysilane represented by the general formula (5).
R¹ₓR⁴_{y}Si(OR⁵)_{4-x-y} (2)
R²ₓR⁴_{y}Si(OR⁵)_{4-x-y} (3)
R³ₓR⁴_{y}Si(OR⁵)_{4-x-y} (4)
R⁴_{z}Si(OR⁵)_{4-z} (5)
Herein R¹ is a monovalent organic group of 2 to 30 carbon atoms having at least one epoxide, R² is a monovalent hydrocarbon group of 2 to 30 carbon atoms having at least one unconjugated double bond group, R³ is a monovalent organic group of 3 to 30 carbon atoms having at least one (meth)acrylic functional group, R⁴ is hydrogen or a monovalent hydrocarbon group of 1 to 20 carbon atoms, R⁵ is hydrogen or a substituted or unsubstituted, monovalent hydrocarbon group of 1 to 10 carbon atoms. The subscript x is 1 or 2, and y is 0 or 1, the sum of x+y is 1 or 2, and z is an integer of 0 to 3.

The monovalent organic group represented by R¹ is of 2 to 30 carbon atoms, preferably 3 to 20 carbon atoms, more preferably 6 to 12 carbon atoms, and has at least one epoxide. The organic group is typically a monovalent hydrocarbon group which has at least one epoxide and may contain an ether bond oxygen atom and/or a nitrogen atom to constitute an amino group, but not limited thereto. Examples include 3-glycidoxypropyl, 2-(3,4-epoxycyclohexyl)ethyl, 2-(2,3-epoxycyclohexyl)ethyl, 3-(N-allyl-N-glycidyl)aminopropyl, and 3-(N,N-glycidyl)aminopropyl.

The monovalent hydrocarbon group represented by R² is of 2 to 30 carbon atoms, preferably 2 to 20 carbon atoms, more preferably 2 to 8 carbon atoms, and has at least one unconjugated double bond group. Examples of suitable monovalent hydrocarbon groups include, but are not limited to, vinyl, allyl, butenyl, isobutenyl, propenyl, isopropenyl, pentenyl, hexenyl, cyclohexenyl, and octenyl.

The monovalent organic group represented by R³ is of 3 to 30 carbon atoms, preferably 5 to 20 carbon atoms, more preferably 5 to 10 carbon atoms, and has at least one (meth)acrylic structure. Exemplary are acrylic and methacrylic functional groups such as CH₂═CHCOO—, CH₂═C(CH₃)COO—, CH₂═CHCO—, and CH₂═C(CH₃)CO—. Examples of the monovalent organic group having such (meth)acryloyl group represented by R³ include, but are not limited to, alkyl groups substituted with one or more acryloyloxy or methacryloyloxy group such as CH₂═CHCOOCH₂CH₂—, CH₂═C(CH₃)COOCH₂CH₂—, [CH₂═C(CH₃)COOCH₂]₃C—CH₂—, (CH₂═CHCOOCH₂)₃C—CH₂—, and (CH₂═CHCOOCH₂)₂CH(C₂H₅)CH₂—. Preferred are CH₂═CHCOOCH₂—, CH₂═C(CH₃)COOCH₂—, CH₂═CHCOOCH₂CH₂CH₂—, and CH₂═C(CH₃)COOCH₂CH₂CH₂—.

The monovalent hydrocarbon group represented by R⁴ is preferably selected from unsubstituted monovalent hydrocarbon groups exclusive of aliphatic unsaturation such as alkenyl, and specifically from alkyl groups of 1 to 10 carbon atoms, aryl groups of 6 to 20 carbon atoms, and aralkyl groups of 7 to 20 carbon atoms. Exemplary of C₁-C₁₀ alkyl groups are methyl, ethyl, propyl, isopropyl, butyl, isobutyl, tert-butyl, pentyl, neopentyl, hexyl, heptyl, cyclohexyl, cycloheptyl, octyl and α-ethylhexyl, with the methyl and ethyl being most preferred. Exemplary of C₆-C₂₀ aryl groups and C₇-C₂₀ aralkyl groups are phenyl, benzyl, tolyl and styryl, with the phenyl being most preferred.

The monovalent hydrocarbon group represented by R⁵ is preferably selected from alkyl groups of 1 to 10 carbon atoms and alkoxy-substituted alkyl groups. Examples include methyl, ethyl, propyl, isopropyl, butyl, isobutyl, tert-butyl, pentyl, neopentyl, hexyl, heptyl, cyclohexyl, cycloheptyl, octyl and α-ethylhexyl, with the methyl and ethyl being most preferred.

Illustrative non-limiting examples of the epoxy-modified organoxysilane having the formula (2) include 3-glycidoxypropyltrimethoxysilane, 2-(3,4-epoxycyclohexylethyl)trimethoxysilane, 3-glycidoxypropyltriethoxysilane, dimethylethoxy-3-glycidoxypropylsilane, and diethoxy-3-glycidoxypropylmethylsilane.

Illustrative non-limiting examples of the unconjugated double bond-bearing organoxysilane having the general formula (3) include vinyltrimethoxysilane, allyltrimethoxysilane, methylvinyldimethoxysilane, divinyldimethoxysilane, trimethoxysilylnorbornene, and 2-(4-cyclohexenylethyl)trimethoxysilane.

Illustrative non-limiting examples of the (meth)acrylic-modified organoxysilane having the general formula (4) include 3-methacryloxypropyltrimethoxysilane, 3-acryloxypropyltrimethoxysilane, 3-methacryloxypropyltriethoxysilane, 3-acryloxypropyltriethoxysilane, methacryloxypropenyltrimethoxysilane, methacryloxypropenyltriethoxysilane, methacryloxymethyltrimethoxysilane, methacryloxymethyltriethoxysilane, methacryloxypropyltris(methoxyethoxy)silane, 3-methacryloxypropyldimethoxymethylsilane, and 3-methacryloxypropyldiethoxymethylsilane.

Illustrative non-limiting examples of the organoxysilane having the general formula (5) include

methyltrimethoxysilane, methyltriethoxysilane, methyltripropoxysilane, methyltributoxysilane, ethyltrimethoxysilane, ethyltriethoxysilane, ethyltripropoxysilane, ethyltributoxysilane, propyltrimethoxysilane, propyltriethoxysilane, propyltripropoxysilane, propyltributoxysilane, phenyltrimethoxysilane, phenyltriethoxysilane, phenyltripropoxysilane, benzyltrimethoxysilane, benzyltriethoxysilane, p-styryltrimethoxysilane,

dimethyldimethoxysilane, dimethyldiethoxysilane, dimethyldipropoxysilane, dimethyldibutoxysilane, diethyldimethoxysilane, diethyldiethoxysilane, diethyldipropoxysilane, diethyldibutoxysilane, dipropyldimethoxysilane, dipropyldiethoxysilane, dipropyldipropoxysilane, dipropyldibutoxysilane, diphenyldihydroxysilane,

trimethylmethoxysilane, trimethylethoxysilane, trimethylpropoxysilane, trimethylbutoxysilane, triethylmethoxysilane, triethylethoxysilane, triethylpropoxysilane, triethylbutoxysilane, tripropylmethoxysilane, tripropylethoxysilane, tripropylpropoxysilane, tripropylbutoxysilane, triphenylhydroxysilane,

trimethoxysilane, triethoxysilane, tetramethoxysilane, tetraethoxysilane, and tetrabutoxysilane.

As regards the mixing proportion of the silanes having formulae (2), (3), (4) and (5), it is preferred that an amount of the epoxy-modified organoxysilane having formula (2) be 10 to 100 mol %, especially 30 to 100 mol % of the overall silanes; an amount of the unconjugated double bond-bearing organoxysilane having formula (3) added optionally be 0 to 60 mol %, especially 10 to 50 mol % of the overall silanes; and an amount of the (meth)acrylic-modified organoxysilane having formula (4) added optionally be 0 to 60 mol %, especially 10 to 50 mol % of the overall silanes; and among the silanes having formula (5), an amount of a monoorganotriorganoxysilane be 0 to 80 mol %, especially 0 to 50 mol % of the overall silanes, an amount of a diorganodiorganoxysilane be 0 to 50 mol %, especially 0 to 20 mol % of the overall silanes, and an amount of a triorganomonoorganoxysilane be 0 to 30 mol %, especially 0 to 20 mol % based on the moles of the silane having formula (1) and 0 to 30 mol %, especially 0 to 20 mol % of the overall silanes when the silane having formula (3) is a tetraorganoxysilane.

The preferred siloxane oligomers include the following oligomers (i), (ii), and (iii).
(i) Siloxane oligomers obtained through (co)hydrolytic condensation of one or more silane compound having the general formula (2):
   R¹ₓR⁴_{y}Si(OR⁵)_{4-x-y} (2)
   wherein R¹, R⁴, R⁵, x and y are as defined above, one or more silane compound having the general formula (3):
   R²ₓR⁴_{y}Si(OR⁵)_{4-x-y} (3)
   wherein R², R⁴, R⁵, x and y are as defined above, and optionally one or more silane compound having the general formula (4):
   R³ₓR⁴_{y}Si(OR⁵)_{4-x-y} (4)
   wherein R³, R⁴, R⁵, x and y are as defined above.
(ii) Siloxane oligomers obtained through (co)hydrolytic condensation of one or more silane compound having the general formula (2):
   R¹ₓR⁴_{y}Si(OR⁵)_{4-x-y} (2)
   wherein R¹, R⁴, R⁵, x and y are as defined above, one or more silane compound having the general formula (4):
   R³ₓR⁴_{y}Si(OR⁵)_{4-x-y} (4)
   wherein R³, R⁴, R⁵, x and y are as defined above, and optionally one or more silane compound having the general formula (5):
   R⁴_{z}Si(OR⁵)_{4-z} (5)
   wherein R⁴, R⁵, and z are as defined above.
(iii) Siloxane oligomers obtained through (co)hydrolytic condensation of one or more silane compound having the general formula (2):
   R¹ₓR⁴_{y}Si(OR⁵)_{4-x-y} (2)
   wherein R¹, R⁴, R⁵, x and y are as defined above, one or more silane compound having the general formula (3):
   R²ₓR⁴_{y}Si(OR⁵)_{4-x-y} (3)
   wherein R², R⁴, R⁵, x and y are as defined above, one or more silane compound having the general formula (4):
   R³ₓR⁴_{y}Si(OR⁵)_{4-x-y} (4)
   wherein R³, R⁴, R⁵, x and y are as defined above, and optionally one or more silane compound having the general formula (5):
   R⁴ₓSi(OR⁵)_{4-z} (5)
   wherein R⁴, R⁵, and z are as defined above.

The process of preparing the organosiloxane oligomer having formula (1) is not particularly limited. In one embodiment using the silanes having formulae (2), (3), (4) and (5), a silanol-bearing cohydrolytic condensate can be obtained by using the epoxy-modified organoxysilane of formula (2) or optionally combining it with the unconjugated double bond-bearing organoxysilane of formula (3), the (meth)acrylic-modified organoxysilane of formula (4) and/or the organoxysilane of formula (5), optionally adding a catalyst and a solvent, and conducting hydrolysis and polycondensation under neutral or weakly alkaline conditions.

As described just above, the (co)hydrolysis is conducted under neutral or weakly alkaline conditions. When the catalyst is used, well-known basic catalysts are useful, for example, NaOH, KOH, sodium siliconate, potassium siliconate, amines and ammonium salts. Inter alia, KOH is preferred.

The (co)hydrolysis is preferably conducted at 5 to 40° C. for 120 minutes or longer. The (co)hydrolyzate thus obtained is then subjected to polycondensation, if necessary. The conditions for polycondensation reaction are crucial in controlling the molecular weight of the silicone resin. Preferably the polycondensation reaction is conducted at 50 to 80° C. for about 60 to 120 minutes.

When the organosiloxane oligomer is obtained through (co)hydrolytic condensation of silanes having formulae (2), (3), (4) and (5) by the above-described process, the silanol is created therein which serves to enhance the primer effect.

The epoxide in R¹ in formula (2), the unconjugated double bond group in R² in formula (3), and the (meth)acryloyl group in R³ in formula (4) are present as reactive substituent groups in the primer and act to enhance the bond strength at the interface between the package or substrate and the encapsulant resin, improving the primer performance.

Diluent

The aforementioned silane coupling agent or epoxide-containing organosiloxane oligomer may be used alone although it is usually dissolved in a diluent prior to use as the primer. The diluent or solvent is not particularly limited as long as it is compatible with the silane coupling agent or epoxide-containing organosiloxane oligomer. Examples of suitable diluents include ethers such as tetrahydrofuran, diglyme and triglyme, ketones such as methyl ethyl ketone and methyl isobutyl ketone, alcohols such as methanol, ethanol, propanol, butanol, 2-propanol, 1-methoxy-2-propanol, 2-ethoxyethanol, 2-ethylhexyl alcohol, 1,4-butanediol, ethylene glycol, and propylene glycol, aromatic hydrocarbons such as toluene and xylene, aliphatic hydrocarbons such as hexane and heptane, and low molecular weight siloxanes such as hexamethyldisiloxane. The diluent is preferably used in amounts of up to about 100,000 parts by weight, more preferably about 100 to 100,000 parts by weight, even more preferably about 400 to 10,000 parts by weight per 100 parts by weight of the organosiloxane oligomer.

Condensation Catalyst

The silane coupling agent or organosiloxane oligomer may be used along with a condensation catalyst. The condensation catalyst used herein is not particular limited as long as it is commonly used in condensation curing type silicone compositions. Suitable catalysts are silanol condensation catalysts including titanium catalysts such as tetrabutyl titanate, tetrapropyl titanate and tetraacetylacetonatotitanium; tin catalysts such as dibutyltin dilaurate, dibutyltin maleate, dibutyltin acetate, tin octylate, tin naphthenate, and dibutyltin acetylacetonate; zinc catalysts such as dimethoxyzinc, diethoxyzinc, zinc 2,4-pentanedionate, zinc 2-ethylhexanoate, zinc acetate, zinc formate, zinc methacrylate, zinc undecylenate, and zinc octylate; aluminum catalysts such as aluminum trisacetylacetonate, aluminum trisethylacetoacetate, and diisopropoxyaluminum ethylacetoacetate; organometallic complex catalysts of zirconium, iron, cobalt and the like; amine catalysts such as butylamine, octylamine, dibutylamine, monoethanolamine, diethanolamine, triethanolamine, diethylenetriamine, triethylenetetramine, oleylamine, cyclohexylamine, benzylamine, diethylaminopropylamine, xylylenediamine, triethylenediamine, guanidine, diphenylguanidine, 2,4,6-tris(dimethylaminomethyl)phenol, morpholine, N-methylmorpholine, 2-ethyl-4-methylimidazole, and DBU; amino group-bearing silane coupling agents such as γ-aminopropyltrimethoxysilane and N-(β-aminoethyl)aminopropylmethyldimethoxysilane; and other well-known silanol condensation catalysts including quaternary ammonium salts such as tetraalkylammonium salts, other acidic catalysts and basic catalysts. These catalysts may be used alone or in admixture.

When used, the amount of the catalyst added is 0.01 to 20 parts by weight, preferably 0.1 to 10 parts by weight, more preferably 0.1 to 3 parts by weight per 100 parts by weight of the overall primer composition excluding the catalyst (usually the total of the silane coupling agent and/or partial hydrolytic condensate thereof and the diluent, or the total of the organosiloxane oligomer and the diluent). Less amounts of the catalyst fail to attain the addition effect, with the curing rate being slowed down. More than necessity amounts of the catalyst achieve no further effect.

Other Components

If necessary, other components may be intimately admixed in the primer composition as long as the primer characteristics are not adversely affected. For example, polymerization inhibitors such as hydroquinone, hydroquinone monomethyl ether, pyrogallol, tert-butylcatechol, and phenothiazine, antioxidants such as BHT and vitamin B, antifoaming agents, and leveling agents such as silicone surfactants and fluorochemical surfactants may be added as appropriate.

Preparation of Primer Composition and Primer Treatment

The primer composition may be prepared by dissolving the silane coupling agent or partial hydrolytic condensate thereof or the organosiloxane oligomer in the diluent, optionally adding the condensation catalyst, optionally further adding the polymerization inhibitor, antioxidant and other components, and mixing them until uniform. The composition thus mixed is ready for use as the primer for semiconductor devices.

Once the semiconductor member is plasma treated, the primer composition may be used, for example, in the following way. Using an applicator such as a spinner or sprayer, the primer composition is applied to the semiconductor member. This is followed by heating or air drying for evaporating off the solvent from the primer composition, thereby forming a coating of the primer composition having a dry thickness of up to 10 μm, preferably up to 1 μm. The lower limit of the coating thickness may be selected as appropriate although it is usually at least 0.01 μm.

Encapsulation

After the semiconductor member is subjected to plasma treatment and subsequent primer treatment in the above-described ways, encapsulating treatment is carried out to encapsulate the semiconductor member.

The encapsulant used for encapsulating the semiconductor member may be selected from well-known encapsulants, depending on the type of semiconductor chip or semiconductor device and the like.

The semiconductor encapsulant is typically a composition comprising a curable resin as the encapsulating resin, a curing agent, and other components such as an antioxidant, anti-discoloring agent, photo-stabilizer, reactive diluent, inorganic filler, flame retardant and organic solvent in amounts not adversely affecting the properties of the curable resin. The curable resin used herein is preferably transparent and typically selected from among curable silicone resins, curable epoxy-silicone hybrid resins, curable epoxy resins, curable acrylic resins, and curable polyimide resins. Depending on a particular curable resin, the curing agent is selected from well-known curing agents and used in an effective amount to cure the curable resin.

Described below is the curable resin in the encapsulating resin composition.

Encapsulating Resin

The preferred semiconductor encapsulating resin is a transparent resin forming a transparent cured product, especially for LED packages. The transparent resins include silicone, epoxy, acrylic, and polyimide base resins, but are not limited thereto. For LED featuring short wavelength and high energy, silicone resins and aromatic-free epoxy resins are preferred. The encapsulating resin is used as an encapsulating resin composition comprising such a resin component as the base, a curing agent and optionally, a curing catalyst, filler and the like. Using an applicator such as a dispenser or spinner, the encapsulating resin composition is directly applied to the semiconductor member which has been subjected to plasma treatment and primer treatment. The encapsulating resin composition thus applied may be cured in the ambient conditions or using a molding machine.

In the transparent resin composition, various additives may be added in such amounts as not to adversely affect the semiconductor device. Suitable additives include antioxidants (e.g., BHT and vitamin B), anti-discoloring agents (e.g., organophosphorus compounds), photo-stabilizers (e.g., hindered amine), reactive diluents (e.g., vinyl ethers, vinylamides, epoxy resins, oxetanes, allyl phthalates, vinyl adipate), reinforcing fillers (e.g., fumed silica, precipitated silica), flame retardant modifiers, fluorescent agents, and organic solvents. The composition may be dyed with a coloring component.

Silicone Resin

The silicone resins used herein include those resins of high hardness type, rubber type and gel type. The curing mechanisms include condensation curing type, addition reaction curing type, and UV curing type. A choice may be made of silicone resins of all types, depending on the type of package.

Epoxy Resin

The epoxy resins used herein include glycidyl ether type epoxy resins such as bisphenol A epoxy resins, bisphenol F epoxy resins, biphenyl type epoxy resins, phenol novolac type epoxy resins, o-cresol novolac type epoxy resins, and brominated epoxy resins; cycloaliphatic epoxy resins; glycidyl ester type epoxy resins; glycidyl amine type epoxy resins; and heterocyclic epoxy resins. For LED featuring short wavelength and high energy, epoxy resins having hydrogenated aromatic rings are preferably used.

These curable epoxy resins cure through mechanisms which include heat curing, UV curing and moisture curing, with the heat curing being most preferred.

Epoxy-Silicone Hybrid Resin

The epoxy-silicone hybrid resin should preferably contain (A) an organosilicon compound having at least one aliphatically unsaturated monovalent hydrocarbon group and at least one silicon-bonded hydroxyl group in a molecule, (B) an aromatic epoxy resin or a hydrogenated epoxy resin in which aromatic rings are partially or completely hydrogenated, and (C) an organohydrogenpolysiloxane as essential components. Preferably, (D) a platinum group metal catalyst and (E) an aluminum curing catalyst may be further compounded. The preferred curing mechanism is heat curing.

By the method of the invention, a semiconductor device, typically LED package, can be fabricated which is highly reliable in that a firm bond or close contact is established between a semiconductor member and an encapsulant resin serving as a protective layer.

### EXAMPLE

Preparation Examples, Examples and Comparative Examples are given below for illustrating the invention, but the invention is not limited thereto.

Preparation of Primer A

A primer composition was prepared by mixing 7 g of 3-glycidoxypropyltrimethoxysilane, 3 g of tetrabutoxytitanate, and 90 g of toluene and filtering the solution through a filter having a pore diameter of 0.8 μm.

Preparation of Primer B

A reactor was charged with 0.5 mol of 2-(3,4-epoxycyclohexylethyl)trimethoxysilane and 0.5 mol of vinyltrimethoxysilane, to which 3.0 mol of deionized water was added. Hydrolysis reaction took place at 40° C. for 8 hours. The hydrolytic condensate thus obtained was dissolved in methanol and the solution was filtered through a filter having a pore diameter of 0.8 μm. From the filtrate, the solvent was distilled off in vacuum at 80° C. and 2 mmHg. By mixing 7 g of the siloxane oligomer thus obtained, 90 g of methanol, and 3 g of zinc octylate, and filtering the solution through a filter having a pore diameter of 0.8 μm, a primer composition was obtained.

Test Methods

Light-Emitting Semiconductor Package

The light-emitting device used is a light-emitting semiconductor package having mounted an LED chip having a light-emitting layer of InGaN and a main emission peak of 470 nm. As shown in FIG. 1, the package includes a housing 1 of glass fiber-reinforced epoxy resin, a light-emitting device 2, lead electrodes 3 and 4, a die bonding material 5, gold wires 6, and an encapsulating resin 7.

Plasma Cleaning

To the light-emitting semiconductor package prior to the encapsulation with the encapsulating resin, a plasma was irradiated for 20 seconds in an argon or oxygen atmosphere at a distance of 15 cm using a plasma dry cleaning system PDC210 (Yamato Science Co., Ltd.) at a power of 250 W.

Primer Treatment

Following the plasma cleaning, the light-emitting semiconductor package was secured to a silicon wafer. The primer composition as prepared above was dipped within the package. Simultaneously with the dipping, the wafer was rotated at 2,000 rpm for 30 seconds. Thereafter, the package was removed from the wafer. The package was air dried at room temperature for 30 minutes when Primer A was used, or heat treated at 150° C. for 10 minutes when Primer B was used.

Thermal Cycling Test

After the plasma treatment and primer treatment, the package was encapsulated with an encapsulating resin composition as shown in Examples, completing a light-emitting semiconductor package as shown in FIG. 1. For comparison purposes, light-emitting semiconductor packages were fabricated without the plasma and primer treatments or without either one of the plasma and primer treatments.

Fifty light-emitting semiconductor packages were fabricated and subjected to a thermal cycling test between a low temperature of −45° C. and a high temperature of 125° C. over 1,000 cycles. On visual observation, the number of samples with outer appearance changes due to cracking and delamination was counted.

### Examples 1-8 & Comparative Examples 1-10

As the encapsulating resin composition, addition reaction curing silicone resin compositions LPS5510 and LPS5520 (by Shin-Etsu Chemical Co., Ltd.) were used. The results corresponding to the respective compositions are shown in Tables 1 and 2.

TABLE 1
Test results of silicone resin LPS5510

| | | | Primer | | Thermal cycling test |
|---|---|---|---|---|---|
| | Plasma treatment | | treatment | | (changed samples/ |
| | argon | oxygen | A | B | test samples) |
| Example 1 | ∘ | — | ∘ | — | 0/50 |
| Example 2 | — | ∘ | ∘ | — | 0/50 |
| Example 3 | ∘ | — | — | ∘ | 0/50 |
| Example 4 | — | ∘ | — | ∘ | 0/50 |
| Comparative | ∘ | — | — | — | 38/50 |
| Example 1 | | | | | |
| Comparative | — | ∘ | — | — | 36/50 |
| Example 2 | | | | | |
| Comparative | — | — | ∘ | — | 28/50 |
| Example 3 | | | | | |
| Comparative | — | — | — | ∘ | 25/50 |
| Example 4 | | | | | |
| Comparative | — | — | — | — | 50/50 |
| Example 5 | | | | | |

TABLE 2
Test results of silicone resin LPS5520

| | | | Primer | | Thermal cycling test |
|---|---|---|---|---|---|
| | Plasma treatment | | treatment | | (changed samples/ |
| | argon | oxygen | A | B | test samples) |
| Example 5 | ∘ | — | ∘ | — | 0/50 |
| Example 6 | — | ∘ | ∘ | — | 0/50 |
| Example 7 | ∘ | — | — | ∘ | 0/50 |
| Example 8 | — | ∘ | — | ∘ | 0/50 |
| Comparative | ∘ | — | — | — | 39/50 |
| Example 6 | | | | | |
| Comparative | — | ∘ | — | — | 36/50 |
| Example 7 | | | | | |
| Comparative | — | — | ∘ | — | 27/50 |
| Example 8 | | | | | |
| Comparative | — | — | — | ∘ | 28/50 |
| Example 9 | | | | | |
| Comparative | — | — | — | — | 50/50 |
| Example 10 | | | | | |

### Examples 9-16 & Comparative Examples 11-20

The encapsulating resin compositions used were a curable epoxy resin composition comprising a heat curable hydrogenated epoxy resin YX8000 (Japan Epoxy Resins Co., Ltd.), an acid anhydride YH1120 (Japan Epoxy Resins Co., Ltd.) as a curing agent, and a curing promoter U-CAT5003 (San-Apro Ltd.), and a similar curable epoxy resin composition using a heat curable hydrogenated epoxy resin YL7170 (Japan Epoxy Resins Co., Ltd.) instead of YX8000. The results corresponding to the respective compositions are shown in Tables 3 and 4.

TABLE 3
Test results of epoxy resin YX8000

| | | | Primer | | Thermal cycling test |
|---|---|---|---|---|---|
| | Plasma treatment | | treatment | | (changed samples/ |
| | argon | oxygen | A | B | test samples) |
| Example 9 | ∘ | — | ∘ | — | 0/50 |
| Example 10 | — | ∘ | ∘ | — | 0/50 |
| Example 11 | ∘ | — | — | ∘ | 0/50 |
| Example 12 | — | ∘ | — | ∘ | 0/50 |
| Comparative | ∘ | — | — | — | 35/50 |
| Example 11 | | | | | |
| Comparative | — | ∘ | — | — | 32/50 |
| Example 12 | | | | | |
| Comparative | — | — | ∘ | — | 25/50 |
| Example 13 | | | | | |
| Comparative | — | — | — | ∘ | 25/50 |
| Example 14 | | | | | |
| Comparative | — | — | — | — | 50/50 |
| Example 15 | | | | | |

TABLE 4
Test results of epoxy resin YL7170

| | | | Primer | | Thermal cycling test |
|---|---|---|---|---|---|
| | Plasma treatment | | treatment | | (changed samples/ |
| | argon | oxygen | A | B | test samples) |
| Example 13 | ∘ | — | ∘ | — | 0/50 |
| Example 14 | — | ∘ | ∘ | — | 0/50 |
| Example 15 | ∘ | — | — | ∘ | 0/50 |
| Example 16 | — | ∘ | — | ∘ | 0/50 |
| Comparative | ∘ | — | — | — | 35/50 |
| Example 16 | | | | | |
| Comparative | — | ∘ | — | — | 31/50 |
| Example 17 | | | | | |
| Comparative | — | — | ∘ | — | 20/50 |
| Example 18 | | | | | |
| Comparative | — | — | — | ∘ | 22/50 |
| Example 19 | | | | | |
| Comparative | — | — | — | — | 50/50 |
| Example 20 | | | | | |

### Examples 17-24 & Comparative Examples 21-30

As the encapsulating resin composition, heat curable epoxy-silicone hybrid resin compositions X-45-720 and X-45-722 (by Shin-Etsu Chemical Co., Ltd.) were used. The results corresponding to the respective compositions are shown in Tables 5 and 6.

TABLE 5
Test results of epoxy-silicone hybrid resin X-45-720

| | | | Primer | | Thermal cycling test |
|---|---|---|---|---|---|
| | Plasma treatment | | treatment | | (changed samples/ |
| | argon | oxygen | A | B | test samples) |
| Example 17 | ∘ | — | ∘ | — | 0/50 |
| Example 18 | — | ∘ | ∘ | — | 0/50 |
| Example 19 | ∘ | — | — | ∘ | 0/50 |
| Example 20 | — | ∘ | — | ∘ | 0/50 |
| Comparative | ∘ | — | — | — | 35/50 |
| Example 21 | | | | | |
| Comparative | — | ∘ | — | — | 32/50 |
| Example 22 | | | | | |
| Comparative | — | — | ∘ | — | 23/50 |
| Example 23 | | | | | |
| Comparative | — | — | — | ∘ | 22/50 |
| Example 24 | | | | | |
| Comparative | — | — | — | — | 50/50 |
| Example 25 | | | | | |

TABLE 6
Test results of epoxy-silicone hybrid resin X-45-722

| | | | Primer | | Thermal cycling test |
|---|---|---|---|---|---|
| | Plasma treatment | | treatment | | (changed samples/ |
| | argon | oxygen | A | B | test samples) |
| Example 21 | ∘ | — | ∘ | — | 0/50 |
| Example 22 | — | ∘ | ∘ | — | 0/50 |
| Example 23 | ∘ | — | — | ∘ | 0/50 |
| Example 24 | — | ∘ | — | ∘ | 0/50 |
| Comparative | ∘ | — | — | — | 34/50 |
| Example 26 | | | | | |
| Comparative | — | ∘ | — | — | 31/50 |
| Example 27 | | | | | |
| Comparative | — | — | ∘ | — | 22/50 |
| Example 28 | | | | | |
| Comparative | — | — | — | ∘ | 24/50 |
| Example 29 | | | | | |
| Comparative | — | — | — | — | 50/50 |
| Example 30 | | | | | |

Japanese Patent Application No. 2005-067587 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A method for preparing a semiconductor device comprising a semiconductor member, the method comprising the steps of:
subjecting the semiconductor member to plasma treatment,
subjecting the semiconductor member to primer treatment with a primer composition, and thereafter,
encapsulating the semiconductor member with an encapsulant.

2. The method of claim 1 wherein the semiconductor device is an LED package.

3. The method of claim 1 wherein said primer composition comprises a silane coupling agent and/or a partial hydrolytic condensate thereof and optionally, a diluent.

4. The method of claim 3 wherein said primer composition further comprises a condensation catalyst.

5. The method of claim 1 wherein said primer composition comprises an organosiloxane oligomer having the average compositional formula (1):
R¹ₐR²_{b}R³_{c}R⁴_{d}(OR⁵)ₑSiO_{(4-a-b-c-d-e)/2} (1)
wherein R¹ is a monovalent organic group of 2 to 30 carbon atoms having at least one epoxide, R² is a monovalent hydrocarbon group of 2 to 30 carbon atoms having at least one unconjugated double bond group, R³ is a monovalent organic group of 3 to 30 carbon atoms having at least one (meth)acrylic functional group, R⁴ is hydrogen or a monovalent hydrocarbon group of 1 to 20 carbon atoms, R⁵ is hydrogen or a substituted or unsubstituted, monovalent hydrocarbon group of 1 to 10 carbon atoms, the subscripts a, b, c, d and e are numbers satisfying the range: 0.1≦a≦1.0, 0≦b≦0.6, 0≦c≦0.6, 0≦d≦0.8, 1.0≦e2.0, and 2.0≦a+b+c+d+e≦3.0, and optionally, a diluent.

6. The method of claim 5 wherein the organosiloxane oligomer having the formula (1) is obtained through (co)hydrolytic condensation of at least one silane compound having the general formula (2):
R¹ₓR⁴_{y}Si(OR⁵)_{4-x-y} (2)
wherein R¹ is a monovalent organic group of 2 to 30 carbon atoms having at least one epoxide, R⁴ is a monovalent hydrocarbon group of 1 to 20 carbon atoms, R⁵ is hydrogen or a substituted or unsubstituted, monovalent hydrocarbon group of 1 to 10 carbon atoms, x is 1 or 2, and y is 0 or 1, the sum of x+y is 1 or 2, and optionally, at least one silane compound having the general formula (3):
R²ₓR⁴_{y}Si(OR⁵)_{4-x-y} (3)
wherein R² is a monovalent hydrocarbon group of 2 to 30 carbon atoms having at least one unconjugated double bond group, R⁴ is a monovalent hydrocarbon group of 1 to 20 carbon atoms, R⁵ is hydrogen or a substituted or unsubstituted, monovalent hydrocarbon group of 1 to 10 carbon atoms, x is 1 or 2, and y is 0 or 1, the sum of x+y is 1 or 2, and optionally, at least one silane compound having the general formula (4):
R³ₓR⁴_{y}Si(OR⁵)_{4-x-y} (4)
wherein R³ is a monovalent organic group of 3 to 30 carbon atoms having at least one (meth)acrylic functional group, R⁴ is a monovalent hydrocarbon group of 1 to 20 carbon atoms, R⁵ is hydrogen or a substituted or unsubstituted, monovalent hydrocarbon group of 1 to 10 carbon atoms, x is 1 or 2, and y is 0 or 1, the sum of x+y is 1 or 2, and optionally, at least one silane compound having the general formula (5):
R⁴ₓSi(OR⁵)_{4-z} (5)
wherein R⁴ is hydrogen or a monovalent hydrocarbon group of 1 to 20 carbon atoms, R⁵ is hydrogen or a substituted or unsubstituted, monovalent hydrocarbon group of 1 to 10 carbon atoms, and z is an integer of 1 to 3.

7. The method of claim 5 wherein said primer composition further comprises a condensation catalyst.

8. The method of claim 1 wherein said encapsulant forms a transparent cured product.

9. The method of claim 1 wherein said encapsulant comprises a curable resin selected from the group consisting of a curable silicone resin, curable epoxy-silicone hybrid resin, curable epoxy resin, curable acrylic resin and curable polyimide resin and forms a transparent cured product.

10. The method of claim 1 wherein said plasma treatment uses a gas selected from the group consisting of argon, nitrogen, oxygen, air and mixtures thereof.
